(19) United States
(12) Patent Application Publication
(10) Pub. No.: US 2013/0316476 A1
(43) Pub. Date: Nov. 28, 2013

(54) Manufacturing method of a retaining wall of an LED

(71) Applicants: Gil Mo Nam, Suwon (KR); DongMyung Kim, Suwon (KR); ChungSeok Lee, Suwon (KR); YoungKi Kim, Suwon (KR); JongSoo Ha, Suwon (KR)

(72) Inventors: Gil Mo Nam, Suwon (KR); DongMyung Kim, Suwon (KR); ChungSeok Lee, Suwon (KR); YoungKi Kim, Suwon (KR); JongSoo Ha, Suwon (KR)

(73) Assignee: AAC TECHNOLOGIES PTE. LTD, Singapore (SG)

(21) Appl. No.: 13/902,160

(22) Filed: May 24, 2013

(30) Foreign Application Priority Data
May 25, 2012 (CN) 201210166656.1

(51) Int. Cl. H01L 33/48

(52) U.S. Cl. CPC H01L 33/48
USPC 438/26

(57) ABSTRACT

A method for manufacturing a retaining wall of an LED is disclosed. The method includes the steps of: providing a substrate and applying a photosensitive layer on the substrate; exposing the photosensitive layer for forming a pattern of the retaining wall of the LED; removing the exposed photosensitive layer by etching process for forming a recess with a shape corresponding to the pattern of the retaining wall; filling the recess with ceramic slurry by screen printing process; drying the left photosensitive layer and the ceramic slurry for hardening the ceramic slurry, and then removing the left photosensitive layer; and sintering the ceramic slurry for forming the ceramic retaining wall.

### FIELD OF THE INVENTION

The present invention relates to the art of LED (Light Emitting Diode), more particularly to a manufacturing method of a retaining wall of an LED used in a portable electric product.

### BACKGROUND OF THE INVENTION

A light-emitting diode (LED) is a semiconductor light source. LEDs are used as indicator lamps in many devices and are increasingly used for other lighting. Appearing as practical electronic components in 1962, early LEDs emitted low-intensity red light, but modern versions are available across the visible, ultraviolet, and infrared wavelengths, with very high brightness.

When a light-emitting diode is switched on, electrons are able to recombine with holes within the device, releasing energy in the form of photons. This effect is called electroluminescence and the color of the light (corresponding to the energy of the photon) is determined by the energy band gap of the semiconductor. An LED is often small in area (less than 1 mm²), and integrated optical components may be used to shape its radiation pattern. LEDs present many advantages over incandescent light sources including lower energy consumption, longer lifetime, improved physical robustness, smaller size, and faster switching. However, LEDs powerful enough for room lighting are relatively expensive and require more precise current and heat management than compact fluorescent lamp sources of comparable output.

With the quick development of electric products, more especially, the portable electric products, such as cellphone, notebook etc., people have stronger requirements for the functions not only of the acoustic performance of communication, but also of the optical performance of the camera. Thereby, LED lens equipped with the portable electronic devices for providing photographic functions are more and more used.

A related LED lens generally comprises a substrate, an LED unit disposed on the substrate, and a lens unit tofor packaging the LED unit.

However, the cost of the lens unit is high as the Lens unit is manufactured by die casting. For solving the problem of high cost, another packaging method following the process sequence “printing-drying-printing” is used to form a retaining wall by screen printing. In this packaging method, simple drying process is used to form the retaining wall by drying the printing materials, which leads the retaining wall to deform due to the pressure from the printing screen during reduplicate printing processes. If the retaining wall needs to reach 150 um high, at least ten times of printing processes should be applied, which may seriously lower the efficiency of the packaging process.

In view of above, a new manufacturing method of a retaining wall of an LED is disclosed to solve the above mentioned problems.

### BRIEF DESCRIPTION OF THE DRAWINGS

FIG. 1 is an illustrative scheme of the first step of a manufacturing method in accordance with an exemplary embodiment of the present disclosure.

FIG. 2 is an illustrative scheme of the second step of the manufacturing method.

FIG. 3 is an illustrative scheme of the third step of the manufacturing method.

FIG. 4 is an illustrative scheme of the fourth step of the manufacturing method.

FIG. 5 is an illustrative scheme of the fifth step of the manufacturing method.

FIG. 6 is an illustrative scheme of the sixth step of the manufacturing method.

FIG. 7 is an isometric view of a retaining wall of an LED in accordance with the exemplary embodiment of the present disclosure.

Many aspects of the embodiment can be better understood with reference to the drawings mentioned above. The components in the drawings are not necessarily drawn to scale, the emphasis instead being placed upon clearly illustrating the principles of the present disclosure. Moreover, in the drawings, like reference numerals designate corresponding parts throughout the several views.

### DESCRIPTION OF ILLUSTRATIVE EMBODIMENT

Reference will now be made to describe an exemplary embodiment of the present disclosure in detail.

The exemplary embodiment provides a manufacturing method of a retaining wall of an LED, and the method comprises the steps of:

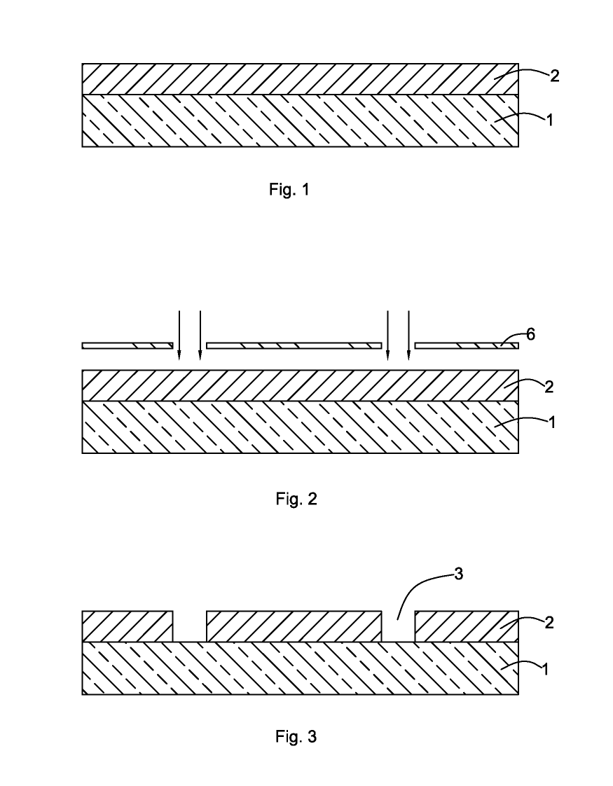

(1) Providing a substrate 1 and applying a photosensitive layer 2 on the substrate 1, as shown in FIG. 1;

(2) Exposing the photosensitive layer 2 for forming a pattern of the retaining wall of the LED, as show in FIG. 2;

(3) Removing the exposed photosensitive layer 2 by etching process for forming a recess 3 with a shape corresponding to the pattern of the retaining wall, as shown in FIG. 3;

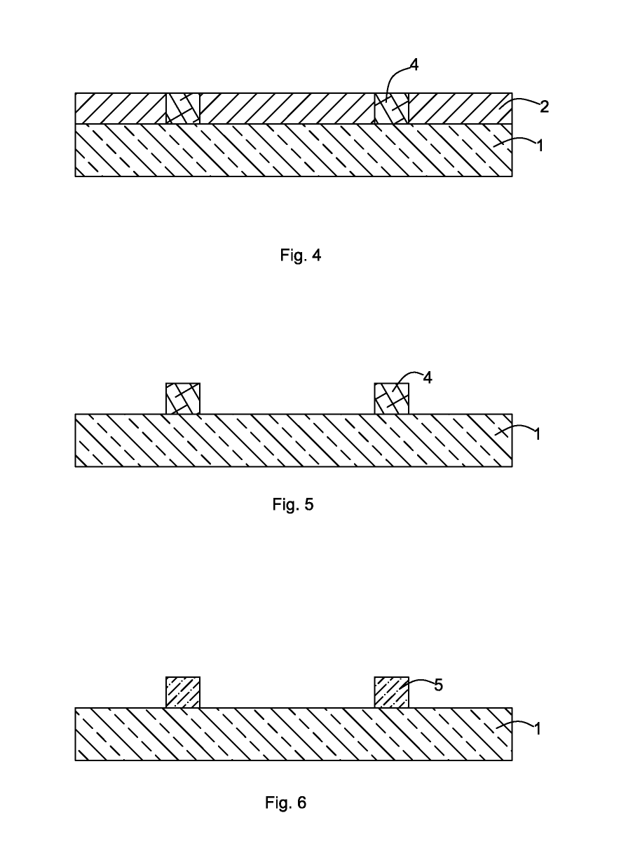

(4) Filling the recess 3 with ceramic slurry 4 by screen printing process, as shown in FIG. 4;

(5) Drying the left photosensitive layer 2 and the ceramic slurry 4 for hardening the ceramic slurry 4, and then removing the left photosensitive layer 2, as shown in FIG. 5; and

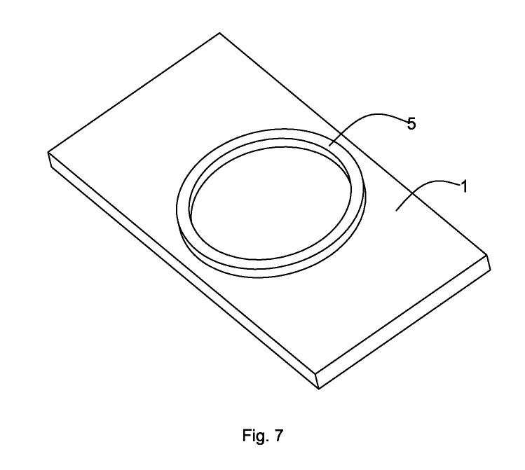

(6) Sintering the ceramic slurry 4 for forming the ceramic retaining wall 5, as shown in FIG. 6.

In step (1), the substrate 1 is optionally a ceramic substrate. In step (2), before the exposing process, a mask layer 6 is applied on the photosensitive layer 2, and the mask layer 6 has a through slot corresponding to the pattern. UV light is used to expose the photosensitive layer 2 along the direction as shown in FIG. 2. In step (4), the ceramic slurry 4 used for filling the recess 3 is photosensitive ceramic slurry. The ceramic slurry 4 optionally comprises white glass-ceramic, dispersant, polymer, monomers, light initiator, and solvent. Optionally, the proportion of the white glass-ceramic is 60˜80%, and the proportion of other matters is 20˜40%.

Glass-ceramics are polycrystalline materials produced through controlled crystallization of base glass. Glass-ceramic materials share many properties with both glasses and ceramics. Glass-ceramics have an amorphous phase and one or more crystalline phases and are produced by a so-called “controlled crystallization” in contrast to a spontaneous crystallization, which is usually not wanted in glass manufacturing. Glass-ceramics have the fabrication advantage of glass as well as special properties of ceramics. Glass-ceramics usually have between 30% [m/m] to 90% [m/m] crystallinity and yield an array of materials with interesting properties like zero porosity, high strength, toughness, translucency or opacity, pigmentation, opalescence, low or even negative thermal expansion, high temperature stability, fluorescence, machinability, ferromagnetism, resorbability or high chemical durability, biocompatibility, bio-activity, ion conductivity, superconductivity, isolation capabilities, low dielectric constant and loss, high resistivity and break down voltage. These properties can be tailored by controlling the base glass composition and by controlled heat treatment/crystallization of base glass.

A dispersant, or a dispersing agent or a plasticizer or a super plasticizer is either a non-surface active polymer or a surface-active substance added to a suspension, usually a colloid, to improve the separation of particles and to prevent settling or clumping. Dispersants consist normally of one or more surfactants, but may also be gases. In this embodiment, the dispersant may be 2-ethylhexyl phosphate, Sodium dodecyl sulfate, sec-hexyl alcohol, cellulose derivatives, polyacrylamide, polyethylene, or guar gum.

In step (6), the sintering temperature is between 600˜900 degrees centigrade. After the sintering process, the retaining wall 7 is formed accordingly, as shown in FIG. 7.

In the manufacturing method of the retaining wall of the LED of the present invention, the ceramic slurry is white glass-ceramic, the retaining wall is provided with a higher hardness after being hardened by the ceramic slurry, which further improves the reflectivity of the retaining wall for increasing heat transfer and luminous efficiency.

Compared with the traditional technology, the manufacturing method of the present disclosure is quite simple and can greatly reduce the process steps of screen printing for improving the production efficiency. The retaining wall is formed by white glass-ceramic slurry, which can further improve reflectivity of the retaining wall for increasing heat transfer and luminous efficiency.

While the present disclosure has been described with reference to the specific embodiment, the description of the disclosure is illustrative and is not to be construed as limiting the disclosure. Various of modifications to the present disclosure can be made to the exemplary embodiment by those skilled in the art without departing from the true spirit and scope of the disclosure as defined by the appended claims.

What is claimed is:

1. A method for manufacturing a retaining wall of an LED, comprising the steps of:
(1) providing a substrate and applying a photosensitive layer on the substrate;
(2) exposing the photosensitive layer for forming a pattern of the retaining wall of the LED;
(3) removing the exposed photosensitive layer by etching process for forming a recess with a shape corresponding to the pattern of the retaining wall;
(4) filling the recess with ceramic slurry by screen printing process;
(5) drying the left photosensitive layer and the ceramic slurry for hardening the ceramic slurry, and then removing the left photosensitive layer; and
(6) sintering the ceramic slurry for forming the ceramic retaining wall.

2. The method as described in claim 1, wherein, the substrate in step (1) is a ceramic substrate.

3. The method as described in claim 1, wherein, the ceramic slurry in step (4) is photosensitive slurry.

4. The method as described in claim 1, wherein, the ceramic slurry comprises white glass-ceramic with a proportion of 60˜80%.

5. The method as described in claim 1, wherein, the sintering temperature in step (6) is between 600˜900 degree centigrade.
